(19) United States
(12) Patent Application Publication
(10) Pub. No.: US 2026/0099097 A1
(43) Pub. Date: Apr. 9, 2026

(54) CONTROL APPARATUS AND CONTROL METHOD

(71) Applicant: Lasertec Corporation, Yokohama (JP)

(72) Inventor: Yoshihiro KATO, Yokohama-shi (JP)

(21) Appl. No.: 19/353,097

(22) Filed: Oct. 8, 2025

(30) Foreign Application Priority Data
Oct. 8, 2024 (JP) 2024-176206

(51) Int. Cl. G03F 7/00

(52) U.S. Cl. CPC G03F 7/70125; G03F 7/70091; G03F 7/7065

(57) ABSTRACT

To provide a control apparatus and a control method that enable inspection accuracy of a mask with a pellicle to be improved. A control apparatus of an optical apparatus equipped with light detecting means for detecting light from a pattern surface of a photomask illuminated by illumination light, the control apparatus including: acquiring means for acquiring pellicle information indicating whether or not a pellicle is mounted on a photomask; and setting means for setting a charge accumulation time in the light detecting means when illuminating a pattern surface of the photomask on which the pellicle is mounted by the optical apparatus to be longer than a charge accumulation time in the light detecting means when illuminating a pattern surface of the photomask on which the pellicle is not mounted by the optical apparatus.

### INCORPORATION BY REFERENCE

This application is based upon and claims the benefit of priority from Japanese patent application No. 2024-176206, filed on October 08, 2024, the disclosure of which is incorporated herein in its entirety by reference for all purposes.

### BACKGROUND

The present disclosure relates to a control apparatus and a control method of an optical apparatus equipped with light detecting means.

Techniques for inspecting defects in patterned masks are known. A pellicle may sometimes be mounted on a mask to protect a pattern surface, and there is a need to inspect the pattern surface using illumination light transmitted through the pellicle.

[Patent Literature 1] Japanese Unexamined Patent Application Publication No. H05-150443

[Patent Literature 2] Japanese Unexamined Patent Application Publication No. 2015-105897

### SUMMARY

When inspecting a mask with a pellicle, there is a problem in that inspection accuracy declines due to the pellicle reflecting or absorbing a part of the illumination light.

The present disclosure has been made in consideration of such a problem and an object thereof is to provide a control apparatus and a control method that enable inspection accuracy of a mask with a pellicle to be improved.

A control apparatus according to an aspect of the present embodiment is a control apparatus of an optical apparatus equipped with light detecting means for detecting light from a pattern surface of a photomask illuminated by illumination light, the control apparatus including: acquiring means for acquiring pellicle information indicating whether or not a pellicle is mounted on a photomask; and setting means for setting a charge accumulation time in the light detecting means when illuminating a pattern surface of the photomask on which the pellicle is mounted by the optical apparatus to be longer than a charge accumulation time in the light detecting means when illuminating a pattern surface of the photomask on which the pellicle is not mounted by the optical apparatus.

A control apparatus according to an aspect of the present embodiment is a control apparatus of an optical apparatus equipped with light detecting means for detecting light from a pattern surface of a photomask that is illuminated by illumination light and on which a pellicle is mounted, the control apparatus including: acquiring means for acquiring pellicle information including a transmittance of the pellicle with respect to the illumination light; and setting means for setting, based on the transmittance, a charge accumulation time in the light detecting means when illuminating the pattern surface, in which the setting means sets the charge accumulation time such that the lower the transmittance, the longer the charge accumulation time, and sets the charge accumulation time to be lower than an upper limit value based on at least any one of an intensity of the illumination light, a heat resistance performance of the pellicle, and a heat dissipation performance of the pellicle.

A control method according to an aspect of the present embodiment is a control method of an optical apparatus equipped with light detecting means for detecting light from a pattern surface of a photomask illuminated by illumination light, the control method including: acquiring pellicle information indicating whether or not a pellicle is mounted on a photomask; and setting a charge accumulation time in the light detecting means when illuminating a pattern surface of the photomask on which the pellicle is mounted by the optical apparatus to be longer than a charge accumulation time in the light detecting means when illuminating the pattern surface of the photomask on which the pellicle is not mounted by the optical apparatus.

A control method according to an aspect of the present embodiment is a control method of an optical apparatus equipped with light detecting means for detecting light from a pattern surface of a photomask that is illuminated by illumination light and on which a pellicle is mounted, the control method including: acquiring pellicle information including a transmittance of the pellicle with respect to the illumination light; and setting, based on the transmittance, a charge accumulation time in the light detecting means when illuminating the pattern surface, in which setting the charge accumulation time involves setting the charge accumulation time such that the lower the transmittance, the longer the charge accumulation time, and setting the charge accumulation time to be lower than an upper limit value based on at least any one of an intensity of the illumination light, a heat resistance performance of the pellicle, and a heat dissipation performance of the pellicle.

According to the present disclosure, a control apparatus and a control method that enable inspection accuracy of a mask with a pellicle to be improved can be provided.

The above and other objects, features and advantages of the present disclosure will become more fully understood from the detailed description given hereinbelow and the accompanying drawings.

### BRIEF DESCRIPTION OF DRAWINGS

FIG. 1 is a configuration diagram illustrating an inspection apparatus according to a first embodiment;

FIG. 2 is a configuration diagram illustrating a control apparatus according to the first embodiment;

FIG. 3 is a diagram to illustrate an example of appropriate imaging conditions in the inspection apparatus;

FIG. 4 is a diagram to illustrate an example of appropriate imaging conditions in the inspection apparatus; and

FIG. 5 is a diagram to illustrate an example of appropriate imaging conditions in the inspection apparatus.

### DESCRIPTION OF EMBODIMENTS

Hereinafter, embodiments of the present disclosure will be described with reference to the drawings. The following description is intended as a description of preferred embodiments of the present disclosure and is not intended to limit the scope of the present disclosure to the following embodiments. In the following description, same reference signs denote substantially similar contents.

### First embodiment

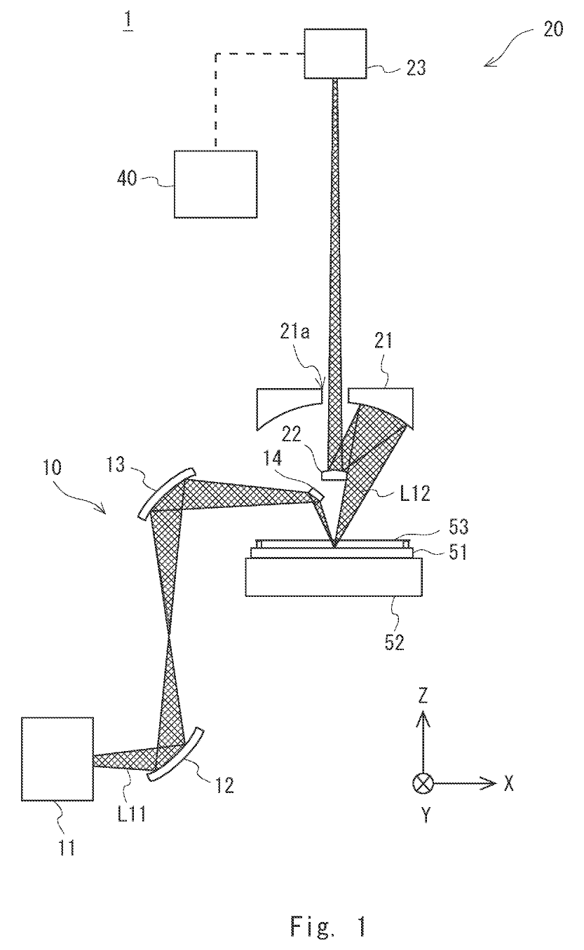

FIG. 1 is a configuration diagram illustrating an inspection apparatus 1 as an optical apparatus according to a first embodiment. The inspection apparatus 1 includes an illuminating optical system 10, an imaging optical system 20, and a control apparatus 40. The illuminating optical system 10 illuminates a photomask 51 using illumination light L11. While a pellicle 53 is mounted on the photomask 51 in FIG. 1, there may be cases where a pattern surface of the photomask 51 not mounted with the pellicle 53 is inspected. In this manner, the inspection apparatus 1 as an optical apparatus inspects a pattern surface based on a result of illuminating the photomask 51 using the illumination light L11. However, the optical apparatus is not limited to an inspection apparatus. The optical apparatus may function as a review apparatus that projects a state of reflected light from the pattern surface or the like when the photomask 51 is illuminated using the illumination light L11.

For example, the illuminating optical system 10 includes a light source 11, an ellipsoidal mirror 12, an ellipsoidal mirror 13, and a drop-in mirror 14. The imaging optical system 20 captures an image of the pattern surface of the photomask 51 illuminated by the illumination light L11. For example, the imaging optical system 20 includes a holed concave mirror 21, a convex mirror 22, and a photodetector 23. The holed concave mirror 21 and the convex mirror 22 constitute a Schwarzschild magnifying optical system. Note that the illuminating optical system 10 and the imaging optical system 20 may further include optical members in addition to the configurations described above or any of the optical members described above may be omitted.

The control apparatus 40 controls the imaging optical system 20. Specifically, the control apparatus 40 sets a charge accumulation time in the photodetector 23 of the imaging optical system 20. The control apparatus 40 may be further configured to be capable of controlling the illuminating optical system 10 so that light intensity of the illumination light L11 can be adjusted. For example, the control apparatus 40 may perform control for inserting a neutral density filter into an optical path of the illumination light L11, control for adjusting an angle of a mirror, or control for adjusting an amount of energy input to the light source 11 or luminous efficiency of the light source 11. The control apparatus 40 will be described later.

The inspection apparatus 1 is an apparatus that inspects a defect, a stain, or the like of the photomask 51. For example, the photomask 51 is an extra ultra violet (EUV) mask that accommodates EUV light. Note that the photomask 51 is not limited to an EUV mask and may be a photomask that accommodates the illumination light L11 with other wavelengths. An XYZ orthogonal coordinate axes system will now be introduced for convenience of description of the inspection apparatus 1. For example, a plane parallel to a stage surface of a stage 52 on which the photomask 51 is arranged is defined as an XY plane and a direction orthogonal to the stage surface is defined as a Z-axis direction. A +Z-axis direction will be referred to as upward for the sake of convenience.

The light source 11 generates the illumination light L11. For example, the illumination light L11 includes EUV light of 13.5 nm that is a same wavelength as an exposure wavelength of the EUV mask being the photomask 51. Note that the illumination light L11 may include light with other wavelengths.

The illumination light L11 generated by the light source 11 is reflected by the ellipsoidal mirror 12. The illumination light L11 reflected by the ellipsoidal mirror 12 travels while being condensed. After coming into focus, the illumination light L11 travels while spreading out.

In addition, the illumination light L11 is incident to a reflective mirror such as the ellipsoidal mirror 13. The illumination light L11 incident to the ellipsoidal mirror 13 is reflected by the ellipsoidal mirror 13, travels while being condensed, and is incident to the drop-in mirror 14. In other words, the ellipsoidal mirror 13 causes the illumination light L11 to be incident to the drop-in mirror 14 as convergent light. The drop-in mirror 14 is arranged above the photomask 51. The illumination light L11 incident to and reflected by the drop-in mirror 14 is incident to the photomask 51. In other words, the drop-in mirror 14 causes the illumination light L11 to be incident to the photomask 51.

The stage 52 is an XYZ driven stage. Moving the stage 52 in an X-axis direction and a Y-axis direction enables a desired region of the photomask 51 to be illuminated. Furthermore, focus adjustment can be performed by moving the stage 52 in the Z-axis direction. In addition, the stage 52 may be rotated with the X axis, the Y axis, and the Z axis as rotational axes. Note that the illuminating optical system 10 and the imaging optical system 20 may be moved and rotated instead of moving and rotating the stage 52 along the X-axis direction, the Y-axis direction, and the Z-axis direction.

The illumination light L11 from the light source 11 illuminates an inspection region of the photomask 51. Reflected light L12 reflected by the photomask 51 is incident to the holed concave mirror 21. A hole 21a is provided at a center of the holed concave mirror 21.

Note that when the pellicle 53 is mounted on the photomask 51, a part of the illumination light L11 is reflected or absorbed by the pellicle 53 and the photomask 51 is illuminated by the illumination light L11 transmitted through the pellicle 53. In addition, a part of the reflected light L12 from the photomask 51 is reflected or absorbed by the pellicle 53 and the reflected light L12 transmitted through the pellicle 53 is incident to the holed concave mirror 21.

The reflected light L12 reflected by the holed concave mirror 21 is incident to the convex mirror 22. The convex mirror 22 reflects the reflected light L12 incident from the holed concave mirror 21 toward the hole 21a of the holed concave mirror 21. The reflected light L12 having passed through the hole 21a is detected by the photodetector 23. The photodetector 23 may be a photodetector that includes a time delay integration (TDI) sensor. The photodetector 23 includes a plurality of imaging elements arranged in a line-shape in one direction. For example, the imaging element is a charge coupled device (CCD). Note that the imaging elements are not limited to CCDs.

As described above, the imaging optical system 20 focuses the reflected light L12 from the photomask 51 illuminated by the illumination light L11, detects the focused reflected light L12 with the photodetector 23, and acquires image data of the photomask 51. The reflected light L12 includes information on a defect and the like of the photomask 51. When a defect is present in the photomask 51, the defect may be observed as a dark image.

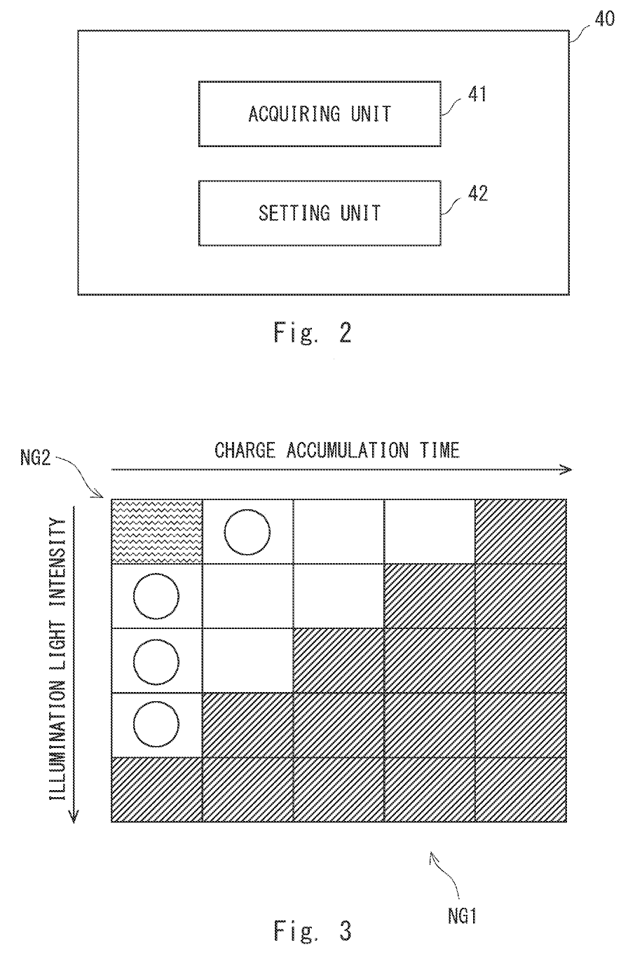

FIG. 2 is a block diagram illustrating the control apparatus 40. The control apparatus 40 includes an acquiring unit 41 and a setting unit 42. Functions of the acquiring unit 41 and the setting unit 42 may be realized by a processor by executing a program loaded to a memory or realized by dedicated hardware.

The acquiring unit 41 acquires pellicle information indicating whether or not the pellicle 53 is mounted on the photomask 51. The pellicle information may include information on a transmittance at which the illumination light L11 is transmitted through the pellicle 53. When the pellicle 53 is not mounted on the photomask 51, the transmittance may be set to 100%.

The acquiring unit 41 may acquire the pellicle information based on information input by a user via an input device such as a keyboard, a mouse, or a touch panel. The acquiring unit 41 may acquire the pellicle information of the photomask 51 to be illuminated from a database storing the pellicle information of each photomask. The acquiring unit 41 may acquire the pellicle information of the photomask 51 by reading identification information written into each photomask. The acquiring unit 41 may acquire the pellicle information of the photomask 51 based on a comparison between a result of illuminating an outer peripheral region of the photomask 51 (generally not covered by the pellicle) and a result of illuminating a central region of the photomask 51 (when the pellicle is mounted, covered by the pellicle).

The acquiring unit 41 may acquire information on an intensity of the illumination light L11. For example, the acquiring unit 41 may acquire information on the intensity of the illumination light L11 based on a detection result by the photodetector 23.

The setting unit 42 sets a charge accumulation time in the photodetector 23 based on the pellicle information. The setting unit 42 may transmit a control signal for setting the charge accumulation time to the photodetector 23. The charge accumulation time may be an exposure time. The charge accumulation time may correspond to a frame rate or a line rate (for example, a line rate of a TDI) and the setting unit 42 may set a frame rate or a line rate in the photodetector 23. The setting unit 42 sets the charge accumulation time when the pellicle 53 is mounted on the photomask 51 to be longer than the charge accumulation time when the pellicle 53 is not mounted on the photomask 51. Accordingly, an inspection accuracy of the photomask 51 with the pellicle 53 can be prevented from declining. The setting unit 42 setting the charge accumulation time when the pellicle 53 is mounted on the photomask 51 to be longer than the charge accumulation time when the pellicle 53 is not mounted on the photomask 51 corresponds to the setting unit 42 setting the number of images (lines) that can be acquired in 1 second when the pellicle 53 is mounted on the photomask 51 to be fewer than the number of images (lines) when the pellicle 53 is not mounted on the photomask 51. Further, the setting unit 42 setting the charge accumulation time when the pellicle 53 is mounted on the photomask 51 longer than the charge accumulation time when the pellicle 53 is not mounted on the photomask 51 corresponds to the setting unit 42 setting the period for acquiring one image (line) when the pellicle 53 is mounted on the photomask 51 to be longer than the period when the pellicle 53 is not mounted on the photomask 51. Note that the number of images (lines) that can be acquired in 1 second or the period for acquiring one image (line) may mean frame rate (line rate).

For example, the setting unit 42 may set the charge accumulation time so that a product of the charge accumulation time and the intensity of light detected by the photodetector 23 is constant. For example, when the transmittance of the pellicle 53 is 0.9, since the illumination light L11 transmitted through the pellicle 53 illuminates the photomask 51 and the reflected light L12 transmitted through the pellicle 53 is detected by the photodetector 23, the intensity of detected light is 0.81 (= 0.9 × 0.9) times the intensity of light detected when the pellicle 53 is not present. In this case, the setting unit 42 may set the charge accumulation time to approximately 1.23 (≈ 1/0.81) times. In other words, when transmittance is denoted by T, the charge accumulation time when illuminating the pattern surface of the photomask on which the pellicle is mounted is denoted by CATp, and the charge accumulation time when illuminating the pattern surface of the photomask on which the pellicle is not mounted is denoted by CATn, the setting unit 42 may set CATp to CATn/T^2 or more.

Accordingly, an inspection and the like of a captured image with respect to the photomask 51 on which the pellicle 53 is mounted can be performed using a same criterion or a process as a case where an inspection and the like of a captured image with respect to the photomask 51 on which the pellicle 53 is not mounted is performed. In addition, an inspection and the like of a captured image with respect to the photomask 51 on which the pellicle 53 is mounted can be performed using a same criterion or a process regardless of the transmittance of the pellicle 53.

For example, when evaluating a captured image of a region to be inspected of the photomask 51 based on a difference from a predetermined reference image, a threshold with respect to the difference can be made the same regardless of the presence or absence of a pellicle or the transmittance of the pellicle and processing is simplified. The control apparatus 40 may include an abnormality determining unit (not illustrated) that determines an abnormality on the pattern surface based on the captured image of the pattern surface and the reference image associated with the captured image differing from one another by more than a predetermined threshold.

In addition, when generating the reference image by inputting information related to design data of the pattern to an image generation model trained by machine learning or the like, an internal coefficient of the image generation model can be made the same regardless of the presence or absence of a pellicle or the transmittance of the pellicle and processing is simplified. Note that the reference image may be an image generated by inputting information related to design data of the pattern to an image generation model trained by machine learning or the like or a captured image of substantially the same die or the photomask 51 taken at different time points. The control apparatus 40 may include a reference image acquiring unit (not illustrated) that acquires the reference image by inputting information related to design data of the pattern surface to a trained image generation model.

On the other hand, if a long charge accumulation time is set, since a same region of the pellicle 53 is to be irradiated by the illumination light L11 over a long period of time, significant damage to the pellicle 53 is expected. Therefore, when the pellicle 53 is mounted on the photomask 51, the setting unit 42 must set the charge accumulation time so as not to exceed a predetermined upper limit value. The upper limit value may be defined based on at least one of the intensity of the illumination light L11, the heat resistance performance of the pellicle 53, and the heat dissipation performance of the pellicle 53.

FIG. 3 shows setting methods of the intensity of the illumination light L11 (also referred to as illumination light intensity) and the charge accumulation time when the pellicle 53 with standard transmittance with respect to the illumination light L11 is mounted on the photomask 51. A horizontal direction in FIG. 3 represents the charge accumulation time, where the more rightward, the longer the charge accumulation time. A vertical direction in FIG. 3 represents the illumination light intensity, where the more downward, the higher the illumination light intensity. Each square represents an imaging condition that combines the charge accumulation time according to a horizontal position of the square with the illumination light intensity according to a vertical position of the square. An imaging condition that combines an i-th (where i is an integer from 1 to 5) lowest illumination light intensity and a j-th (where j is an integer from 1 to 5) shortest charge accumulation time with each other is also referred to as an imaging condition Aij.

Imaging conditions A15, A24 to A25, A33 to A35, A42 to A45, and A51 to A55 included in a region NG1 may cause damage to the pellicle 53. Under an imaging condition A11 included in a region NG2, the intensity of light detected by the photodetector 23 is low and may result in low inspection accuracy. Therefore, the setting unit 42 must select the imaging condition from appropriate imaging conditions A12 to A14, A21 to A23, A31 to A32, and A41 that are not included in the regions NG1 and NG2.

When the illumination light intensity is fixed, the setting unit 42 may select the imaging condition with the shortest charge accumulation time from among appropriate imaging conditions. Accordingly, an inspection time can be shortened. For example, the setting unit 42 may select the imaging condition A12 from among the imaging conditions A12 to A14. In a similar manner, the setting unit 42 may select the imaging condition A21 from among the appropriate imaging conditions A21 to A23 and select the imaging condition A31 from among the appropriate imaging conditions A31 to A32. Symbol "○" indicates an imaging condition with a shortest charge accumulation time for each illumination light intensity. When the illumination light intensity is variable, the setting unit 42 may vary the illumination light intensity so that the charge accumulation time becomes shorter. For example, the setting unit 42 may select the imaging condition A21 with the short charge accumulation time from among the imaging conditions A12 and A21. At this point, the setting unit 42 may perform control for changing the illumination light intensity.

The setting unit 42 may select the imaging condition based on the illumination light intensity acquired by the acquiring unit 41.

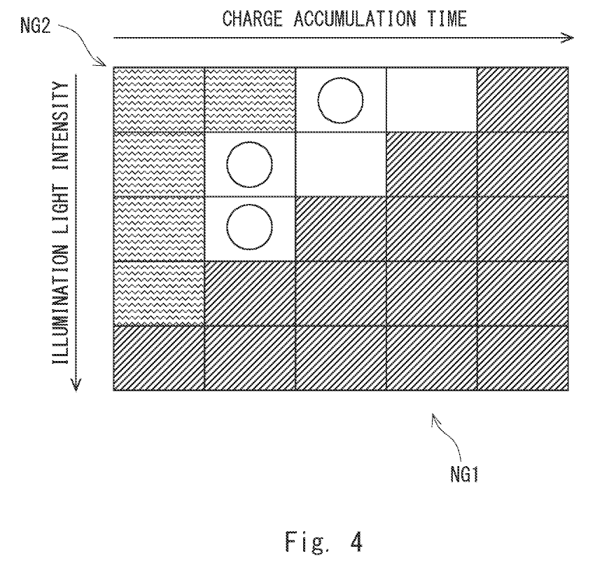

FIG. 4 shows appropriate imaging conditions A13 to A14, A22 to A23, and A31 when the pellicle 53 with slightly low transmittance with respect to the illumination light L11 is mounted on the photomask 51. Since the light intensity detected by the photodetector 23 decreases, a comparison between FIGS. 3 and 4 reveals that imaging conditions A12, A21, A31, and A41 have been added to the region NG2. When the illumination light intensity is fixed, the setting unit 42 may select the imaging condition A13 from among the imaging conditions A13 to A14 so as to make the charge accumulation time shorter. In a similar manner, the setting unit 42 may select the imaging condition A22 from among the imaging conditions A22 to A23. When an appropriate imaging condition does not exist at a given illumination light intensity, the setting unit 42 can select an appropriate imaging condition by reducing the illumination light intensity. For example, while the imaging condition A42 is an inappropriate imaging condition, the imaging condition A32 obtained by reducing the illumination light intensity of the imaging condition A42 is an appropriate imaging condition. The setting unit 42 may perform control for reducing the illumination light intensity.

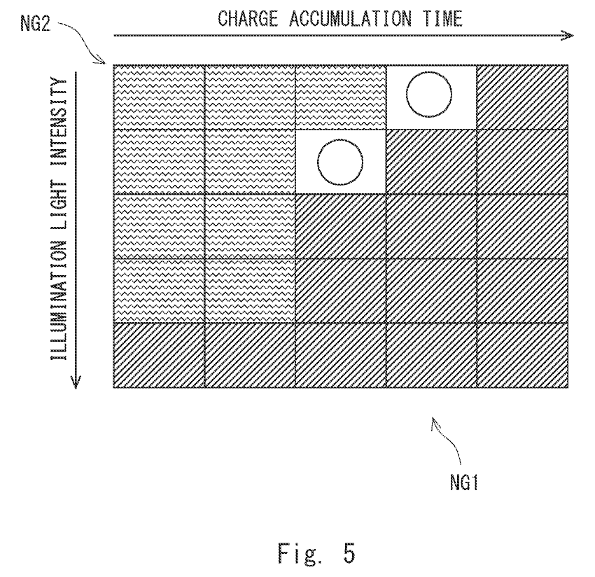

FIG. 5 shows appropriate imaging conditions A14 and A23 when the pellicle 53 with particularly low transmittance with respect to the illumination light L11 is mounted on the photomask 51. A comparison between FIGS. 4 and 5 reveals that imaging conditions A13, A22, A32, and A42 have been added to the region NG2. The imaging condition A42 is included in both the region NG1 and the region NG2.

Referring to FIGS. 3 to 5, the lower the transmittance of the pellicle 53, the greater a lower limit value of the charge accumulation times included in the appropriate imaging conditions. In addition, the higher the intensity of the illumination light, the smaller an upper limit value of the charge accumulation times included in the appropriate imaging conditions. The lower limit value of the charge accumulation time corresponding to a lower transmittance compared to a higher transmittance is greater than the lower limit value of the charge accumulation time corresponding to the higher transmittance. The upper limit value of the charge accumulation time corresponding to a higher intensity of the illumination light compared to a lower intensity is smaller than the upper limit value of the charge accumulation time corresponding to the lower intensity.

A range of the region NG1 may be defined according to a heat resistance performance or a heat dissipation performance based on a thickness, a material, a molecular structure, and the like of the pellicle 53. For example, when the pellicle 53 with a low heat resistance performance or the pellicle 53 with a low heat dissipation performance is mounted on the photomask 51, conditions included in the region NG1 may increase as compared to when the pellicle 53 with a high heat resistance performance or the pellicle 53 with a high heat dissipation performance is mounted on the photomask 51, in which case an imaging condition with a higher illumination light intensity or an imaging condition with a longer charge accumulation time may be added to the region NG1. Pellicle information may include information on the thickness, the material, and the like of the pellicle or information related to the heat resistance performance or the heat dissipation performance of the pellicle. The setting unit 42 can set the charge accumulation time or the like using a map indicating appropriate imaging conditions according to the pellicle information.

The setting unit 42 may set one charge accumulation time with respect to an entire illumination region of the pattern surface of the photomask 51. In other words, using the charge accumulation time selected and set from among appropriate imaging conditions, the setting unit 42 inspects the entire illumination region (entire inspection region) of the pattern surface of the photomask 51 without changing the setting of the charge accumulation time. Accordingly, captured images of the photomask 51 can be inspected according to the same criterion over the entire illumination region (entire inspection region).

With the control apparatus according to the first embodiment, both the photomask 51 on which the pellicle 53 is mounted and the photomask 51 on which the pellicle 53 is not mounted can be inspected with accuracy. In addition, the control apparatus according to the first embodiment can also reduce damage that accumulates on the pellicle 53 mounted on the photomask 51.

While the vertical axes in FIGS. 3 to 5 represent illumination light intensity, the vertical axes are not limited thereto.

The vertical axes in FIGS. 3 to 5 may represent the heat resistance performance of the pellicle 53. In this case, the more downward, the lower the heat resistance performance. Therefore, the lower the heat resistance performance of the pellicle 53, the smaller the upper limit value of the charge accumulation times included in the appropriate imaging conditions.

The vertical axes in FIGS. 3 to 5 may represent the heat dissipation performance of the pellicle 53. In this case, the more downward, the lower the heat dissipation performance. Therefore, the lower the heat dissipation performance of the pellicle 53, the smaller the upper limit value of the charge accumulation times included in the appropriate imaging conditions. The upper limit value of the charge accumulation time corresponding to the pellicle with a lower heat dissipation performance compared to a higher heat dissipation performance is smaller than the upper limit value of the charge accumulation time corresponding to the pellicle with the higher heat dissipation performance.

The vertical axes in FIGS. 3 to 5 may represent an index based on high illumination light intensity and low heat resistance performance of the pellicle 53. In this case, the more downward, the larger the index. Therefore, the higher the illumination light intensity and the lower the heat resistance performance of the pellicle 53, the smaller the upper limit value of the charge accumulation times included in the appropriate imaging conditions.

The vertical axes in FIGS. 3 to 5 may represent an index based on high illumination light intensity and low heat dissipation performance of the pellicle 53. In this case, the more downward, the larger the index. Therefore, the higher the illumination light intensity and the lower the heat dissipation performance of the pellicle 53, the smaller the upper limit value of the charge accumulation times included in the appropriate imaging conditions.

The vertical axes in FIGS. 3 to 5 may represent an index based on low heat resistance performance of the pellicle 53 and low heat dissipation performance of the pellicle 53. In this case, the more downward, the larger the index. Therefore, the lower the heat resistance performance of the pellicle 53 and the lower the heat dissipation performance of the pellicle 53, the smaller the upper limit value of the charge accumulation times included in the appropriate imaging conditions.

The vertical axes in FIGS. 3 to 5 may represent an index based on high illumination light intensity, low heat resistance performance of the pellicle 53, and low heat dissipation performance of the pellicle 53. In this case, the more downward, the larger the index. Therefore, the higher the illumination light intensity, the lower the heat resistance performance of the pellicle 53, and the lower the heat dissipation performance of the pellicle 53, the smaller the upper limit value of the charge accumulation times included in the appropriate imaging conditions.

While embodiments of the present disclosure have been described above, the present disclosure includes appropriate modifications that do not impair its purpose and advantages and, further, the present disclosure is not limited by the above embodiments. In addition, combinations of the respective configurations of the first and second embodiments are also within the scope of the technical concepts of the present disclosure.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A control apparatus for an optical apparatus equipped with at least one light detector configured to detect light from a pattern surface of a photomask illuminated by illumination light, the control apparatus comprising:
at least one memory storing instructions; and
at least one processor coupled to the at least one memory and configured, by executing the instructions, to:
acquire pellicle information indicating whether a pellicle is mounted on the photomask; and
set a charge accumulation time of the at least one light detector, wherein the charge accumulation time of the at least one light detector is longer when the optical apparatus illuminates the pattern surface of the photomask on which the pellicle is mounted than when the optical apparatus illuminates a pattern surface of the photomask on which the pellicle is not mounted.

2. The control apparatus according to claim 1, wherein the at least one processor is further configured, by executing the instructions, to:
acquire the pellicle information including a transmittance of the pellicle with respect to the illumination light; and
set the charge accumulation time so as not to be less than a lower limit value based on the transmittance when the pellicle is mounted on the photomask.

3. The control apparatus according to claim 2, wherein the lower limit value of the charge accumulation time corresponding to a lower transmittance compared to a higher transmittance is greater than the lower limit value of the charge accumulation time corresponding to the higher transmittance.

4. The control apparatus according to claim 1, wherein when the pellicle is mounted on the photomask, the at least one processor is further configured, by executing the instructions, to set the charge accumulation time to be less than an upper limit value based on at least one of an intensity of the illumination light, a heat resistance performance of the pellicle, and a heat dissipation performance of the pellicle.

5. The control apparatus according to claim 4, wherein the upper limit value of the charge accumulation time corresponding to a higher intensity of the illumination light compared to a lower intensity is smaller than the upper limit value of the charge accumulation time corresponding to the lower intensity.

6. The control apparatus according to claim 4, wherein the upper limit value of the charge accumulation time corresponding to the pellicle with a lower heat dissipation performance compared to a higher heat dissipation performance is smaller than the upper limit value of the charge accumulation time corresponding to the pellicle with the higher heat dissipation performance.

7. The control apparatus according to claim 1, wherein the at least one processor is further configured, by executing the instructions, to:
determine an abnormality on the pattern surface based on a captured image of the pattern surface obtained from a detection result of light by the at least one light detector and a reference image associated with the captured image, the captured image and the reference image differing by more than a predetermined threshold, and
wherein the threshold when illuminating the pattern surface of the photomask on which the pellicle is mounted by the optical apparatus is approximately the same as the threshold when illuminating the pattern surface of the photomask on which the pellicle is not mounted by the optical apparatus.

8. The control apparatus according to claim 7, wherein the at least one processor is further configured, by executing the instructions, to:
acquire the reference image by inputting information related to design data of the pattern surface to a trained image generation model, and
wherein a coefficient of the image generation model when illuminating the pattern surface of the photomask on which the pellicle is mounted by the optical apparatus is approximately the same as a coefficient of the image generation model when illuminating the pattern surface of the photomask on which the pellicle is not mounted by the optical apparatus.

9. A control apparatus for an optical apparatus equipped with at least one light detector configured to detect light from a pattern surface of a photomask that is illuminated by illumination light and on which a pellicle is mounted, the control apparatus comprising:
at least one memory storing instructions; and
at least one processor coupled to the at least one memory and configured, by executing the instructions, to:
acquire pellicle information including a transmittance of the pellicle with respect to the illumination light; and
set, based on the transmittance, a charge accumulation time of the at least one light detector when illuminating the pattern surface,
wherein the at least one processor is further configured, by executing the instructions, to:
set the charge accumulation time for a lower transmittance compared to a higher transmittance to be greater than the charge accumulation time for the higher transmittance, and
set the charge accumulation time to be less than an upper limit value based on at least one of an intensity of the illumination light, a heat resistance performance of the pellicle, and a heat dissipation performance of the pellicle.

10. The control apparatus according to claim 9, wherein the upper limit value of the charge accumulation time corresponding to a higher intensity of the illumination light compared to a lower intensity is smaller than the upper limit value of the charge accumulation time corresponding to the lower intensity.

11. The control apparatus according to claim 9, wherein the upper limit value of the charge accumulation time corresponding to the pellicle with a lower heat dissipation performance compared to a higher heat dissipation performance is smaller than the upper limit value of the charge accumulation time corresponding to the pellicle with the higher heat dissipation performance.

12. The control apparatus according to claim 9, wherein the at least one processor is further configured, by executing the instructions, to:
determine an abnormality on the pattern surface based on a captured image of the pattern surface obtained from a detection result of light by the at least one light detector and a reference image associated with the captured image, wherein the captured image and the reference image differ by more than a predetermined threshold, and
wherein the threshold when illuminating the pattern surface of the photomask on which a pellicle with a first transmittance is mounted by the optical apparatus is approximately the same as the threshold when illuminating the pattern surface of the photomask on which a pellicle with a second transmittance is mounted by the optical apparatus.

13. The control apparatus according to claim 12, wherein the at least one processor is further configured, by executing the instructions, to:
acquire the reference image by inputting information related to design data of the pattern surface to a trained image generation model, and
wherein a coefficient of the image generation model when illuminating the pattern surface of the photomask on which the pellicle is mounted by the optical apparatus is approximately the same as a coefficient of the image generation model when illuminating the pattern surface of the photomask on which the pellicle is not mounted by the optical apparatus.

14. The control apparatus according to claim 1, wherein the at least one processor is further configured, by executing the instructions, to set one charge accumulation time with respect to an entire illumination region of the pattern surface of the photomask.

15. The control apparatus according to claim 2, wherein the at least one processor is further configured, by executing the instructions, to set the charge accumulation time when illuminating the pattern surface of the photomask on which the pellicle is mounted (CATp) to be not less than CATn/T^2,
where T denotes the transmittance, CATp denotes the charge accumulation time for the photomask on which the pellicle is mounted, and CATn denotes the charge accumulation time for the photomask on which the pellicle is not mounted.

16. The control apparatus according to claim 1, wherein the at least one processor is further configured, by executing the instructions, to set the charge accumulation time so that a product of the charge accumulation time and an intensity of light detected by the at least one light detector is substantially constant.

17. A control method of an optical apparatus equipped with at least one light detector configured to detect light from a pattern surface of a photomask illuminated by illumination light, the control method comprising:
acquiring pellicle information indicating whether or not a pellicle is mounted on the photomask; and
setting a charge accumulation time of the at least one light detector, wherein the charge accumulation time of the at least one light detector is longer when illuminating the pattern surface of the photomask on which the pellicle is mounted than when illuminating the pattern surface of the photomask on which the pellicle is not mounted by the optical apparatus.

18. A control method of an optical apparatus equipped with at least one light detector configured to detect light from a pattern surface of a photomask that is illuminated by illumination light and on which a pellicle is mounted, the control method comprising:
acquiring pellicle information including a transmittance of the pellicle with respect to the illumination light; and
setting, based on the transmittance, a charge accumulation time of the at least one light detector when illuminating the pattern surface,
wherein setting the charge accumulation time involves setting the charge accumulation time for a lower transmittance compared to a higher transmittance to be greater than the charge accumulation time for the higher transmittance, and setting the charge accumulation time to be less than an upper limit value based on at least one of an intensity of the illumination light, a heat resistance performance of the pellicle, and a heat dissipation performance of the pellicle.
